(19) United States
(12) Patent Application Publication
(10) Pub. No.: US 2004/0175926 A1
(43) Pub. Date: Sep. 9, 2004

(54) METHOD FOR MANUFACTURING A SEMICONDUCTOR COMPONENT HAVING A BARRIER-LINED OPENING

(75) Inventors: Pin-Chin Connie Wang, Menlo Park, CA (US); Richard J. Huang, Cupertino, CA (US)

Correspondence Address: Rennie Dover, The Cavanagh Law Firm, Ste. 2400, 1850 N. Central Avenue, Phoenix, AZ, 85004, US

(73) Assignee: ADVANCED MICRO DEVICES, INC.

(21) Appl. No.: 10/383,318

(22) Filed: Mar. 7, 2003

(51) Int. Cl. H01L 21/4763; H01L 23/48

(52) U.S. Cl. 438/627

(57) ABSTRACT

A semiconductor component having a metallization system that includes a thin conformal multi-layer barrier structure and a method for manufacturing the semiconductor component. A layer of dielectric material is formed over a lower level interconnect. A hardmask is formed over the dielectric layer and an opening is etched through the hardmask into the dielectric layer. The opening is lined with a thin conformal multi-layer barrier using atomic layer deposition. The multi-layer barrier lined opening is filled with an electrically conductive material which is planarized.

### FIELD OF THE INVENTION

The present invention relates, in general, to a metallization system suitable for use in a semiconductor component and, more particularly, to a semiconductor component having a low resistance metallization system and to a method for manufacturing the semiconductor component.

### BACKGROUND OF THE INVENTION

Semiconductor component manufacturers are constantly striving to increase the speeds of their components. Because a semiconductor component, such as a microprocessor, contains up to a billion transistors or devices, the focus for increasing speed has been to decrease gate delays of the semiconductor devices that make up the semiconductor component. As a result, the gate delays have been decreased to the point that speed is now primarily limited by the propagation delay of the metallization system used to interconnect the semiconductor devices with each other and with elements external to the semiconductor component. Metallization systems are typically comprised of a plurality of interconnect layers vertically separated from each other by a dielectric material and electrically coupled to each other by metal-filled vias or conductive plugs. Each layer contains metal lines, metal-filled vias, or combinations thereof separated by an insulating material. A figure of merit describing the delay of the metallization system is its Resistance-Capacitance (RC) delay. The RC delay can be derived from the resistance of the metal layer and the associated capacitance within and between different layers of metal in the metallization system. More particularly, the RC delay is given by:

RC=(ρ*ε*1²/(tₘ*t_{diel}))

where:

ρ is the resistivity of the metallic interconnect layer;

ε is the dielectric constant or permittivity of the dielectric material;

1 is the length of the metallic interconnect;

tₘ is the thickness of the metal; and

tₒₓ is the thickness of the dielectric material.

The RC delay may be reduced by decreasing the resistivity and/or the capacitance of the metallization system. Two commonly used techniques for decreasing these parameters are the single-damascene process and the dual-damascene process. In the single-damascene process, trenches and/or vias are etched into a first dielectric layer and subsequently filled with metal. A second dielectric layer is formed over the first dielectric layer and trenches and/or vias are formed therein. The trenches and/or vias in the second dielectric layer are then filled with metal, which contacts the metal in selected vias or trenches in the first dielectric layer. In the dual-damascene process, two levels of trenches and/or vias are formed using one or multiple layers of dielectric material. The trenches and/or vias are then filled with metal in a single step such that the metal in a portion of the vias contacts the metal in a portion of the trenches. After formation of the trenches and/or vias and before filling them with metal, the trenches and/or vias are typically lined with an electrically conductive single layer barrier, which prevents diffusion of copper through the sidewalls of the trenches and/or vias. The resistivity of the metallization system is governed, in part, by the combination of the metal filling the trenches and/or vias and the single layer barrier. Because the resistivity of copper is much lower than that of the barrier layer, one technique for lowering the resistivity of the metallization system has been to make the single layer barrier as thin as possible using Plasma Vapor Deposition (PVD). One drawback of this technique is that gaps in coverage by the single layer barrier occur, which result in copper contacting the underlying material. The copper then diffuses into the underlying material which degrades the reliability of the semiconductor components. In addition, the absence of the single layer barrier over an underlying copper layer increases the probability of electromigration failures. Another drawback of having gaps in the single layer barrier is that the deposited copper tends to adhere poorly to the underlying layer exposed by the gaps, resulting in portions of the metallization system peeling from the semiconductor component and causing it to fail. Yet another drawback is that because the single layer barrier is typically non-uniform, voids or “keyholes” may arise in the metal filling the trenches and/or vias, thereby increasing the resistance of the metallization system.

Accordingly, what is needed is a semiconductor component having a metallization system with a barrier of uniform thickness and without gaps and a method for manufacturing the semiconductor component.

### SUMMARY OF THE INVENTION

The present invention satisfies the foregoing need by providing a semiconductor component and a method for manufacturing the semiconductor component having a multi-layer barrier structure. In accordance with one aspect, the present invention includes providing a semiconductor substrate having a major surface and an interconnect layer over the major surface. A dielectric material is formed over the interconnect layer and an opening is formed in the dielectric material. A multi-layer barrier structure is formed in the opening using atomic layer deposition to form a multi-layer barrier-lined opening. The multi-layer barrier-lined opening is filled with an electrically conductive material.

In accordance with another aspect, the present invention comprises forming a damascene structure over a lower metal level, where the damascene structure includes an insulating material having a major surface and an opening extending into the insulating material. A multi-layer barrier is formed in the opening and an electrically conductive material is formed over the multi-layer barrier.

In accordance with yet another aspect, the present invention comprises a method for reducing electromigration in a semiconductor component. A damascene structure is provided over a lower electrically conductive level, where the damascene structure includes a dielectric material having a major surface and an opening extending into the dielectric material. The opening and a portion of the major surface of the first layer of electrically conductive material are lined with a barrier material to form a barrier-lined opening. The first layer of electrically conductive material is lined with a second layer of electrically conductive material such that the first and second layers of electrically conductive material cooperate to form a multi-layer barrier film. A metal is disposed over the multi-layer barrier film and fills the multi-layer barrier lined opening.

In accordance with yet another aspect, the present invention comprises a semiconductor component having a damascene structure over a lower electrically conductive level, wherein the damascene structure comprises a dielectric material having a major surface and an opening extending into the dielectric material. A multi-layer barrier lines the opening and a portion of the major surface. An electrically conductive material is disposed on the multi-layer barrier in the opening.

### BRIEF DESCRIPTION OF THE DRAWINGS

The present invention will be better understood from a reading of the following detailed description, taken in conjunction with the accompanying drawing figures, in which like reference numbers designate like elements and in which:

FIGS. 1-4 are enlarged cross-sectional side views of a semiconductor component during manufacture in accordance with an embodiment of the present invention.

### DETAILED DESCRIPTION

Generally, the present invention provides a semiconductor component having a metallization system with a thin conformal multi-layer barrier structure that reduces electromigration and allows for the formation of copper (or other suitable metal) interconnects having an increased cross-sectional area and a lower resistance. The metallization system may be manufactured using, for example, a damascene process, by forming a trench and/or via in a dielectric stack comprising an insulating layer having an anti-reflective coating layer disposed thereon. The trench and/or via is lined with a multi-layer conformal barrier and then filled with an electrically conductive material such as, for example, copper. In accordance with one aspect of the present invention, the conformal multi-layer barrier comprises a protective layer conformally lining the trenches and/or vias and a capping layer overlying the protective layer. The protective and capping layers are formed using an atomic layer deposition technique in conjunction with a non-halide precursor or with an organometallic precursor. The protective layer has a thickness ranging between approximately 5 Angstroms (Å) and approximately 60 Å and the conformal capping layer has a thickness ranging from one monolayer to about 10 Å. Preferably, the capping layer ranges from about 1 Å to about 5 Å. The protective layer and the capping layer cooperate to form the conformal multi-layer barrier. The electrically conductive material overlying the conformal multi-layer barrier is planarized (or polished) to form filled trenches and/or vias, e.g., copper-filled trenches when the electrically conductive material is copper. An advantage of forming a multi-layered barrier using atomic layer deposition is that the multi-layered barrier is a thin conformal structure having a low resistance. Another advantage of the present invention is that it reduces electromigration.

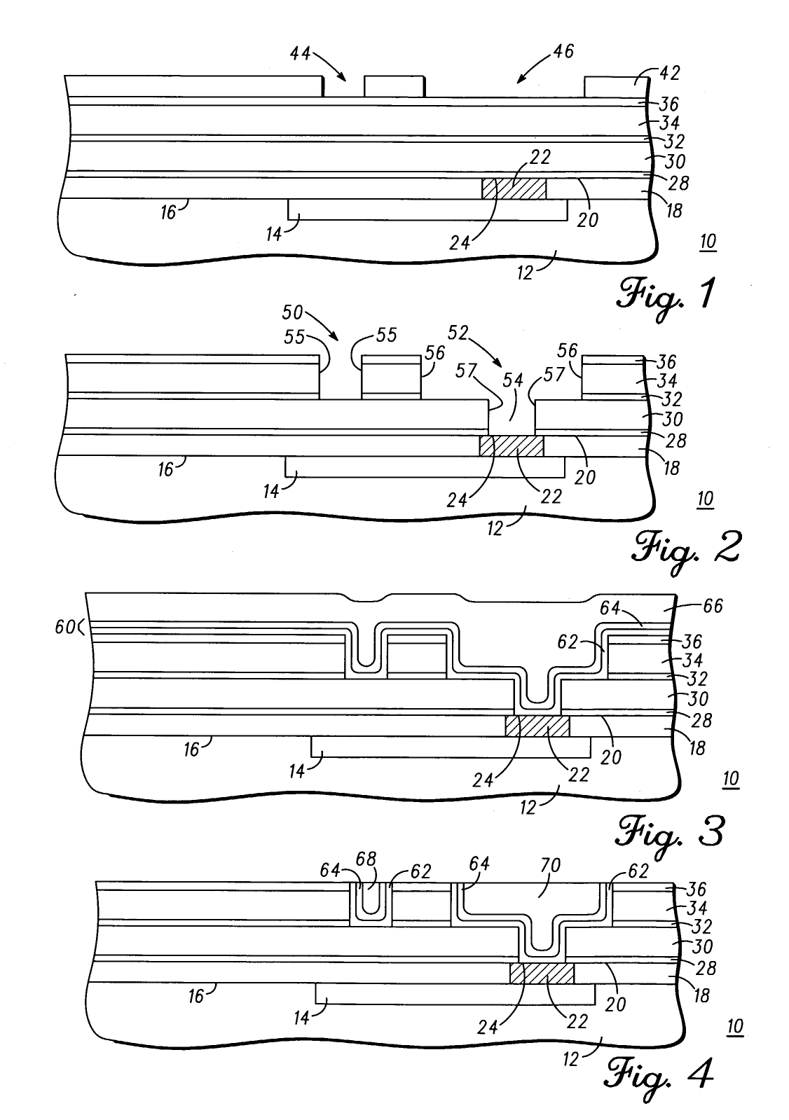

FIG. 1 is an enlarged cross-sectional side view of a semiconductor component 10 during an intermediate stage of manufacture in accordance with an embodiment of the present invention. What is shown in FIG. 1 is a portion of a semiconductor substrate 12 in which a semiconductor device 14 has been fabricated. Semiconductor substrate 12 has a major surface 16. It should be understood that semiconductor device 14 has been shown in block form and that the type of semiconductor device is not a limitation of the present invention. Suitable semiconductor devices include active elements such as, for example, insulated gate field effect transistors, complementary insulated gate field effect transistors, junction field effect transistors, bipolar junction transistors, diodes, and the like, as well as passive elements such as, for example, capacitors, resistors, and inductors. Likewise, the material of semiconductor substrate 12 is not a limitation of the present invention. Substrate 12 can be silicon, Silicon-On-Insulator (SOI), Silicon-On-Sapphire (SOS), silicon germanium, germanium, an epitaxial layer of silicon formed on a silicon substrate, or the like. In addition, semiconductor substrate 12 may be comprised of compound semiconductor materials such as gallium-arsenide, indium-phosphide, or the like.

A dielectric material 18 having a major surface 20 is formed on semiconductor substrate 12 and an electrically conductive portion 22 having a major surface 24 is formed in a portion of dielectric material 18. By way of example, electrically conductive portion 22 is metal. Metal layer 22 may be referred to as Metal-1, a lower electrically conductive level, a lower metal level, an underlying structure, or an underlying interconnect structure. The combination of dielectric material 18 and electrically conductive portion 22 is referred to as an interconnect layer. When electrically conductive portion 22 is metal, the interconnect layer is also referred to as a metal interconnect layer or a conductive level. Techniques for forming semiconductor devices such as device 14, dielectric material 18, and metal layer 22 are known to those skilled in the art.

An etch stop layer 28 having a thickness ranging between approximately 5 Å and approximately 1,000 Å is formed on major surfaces 20 and 24. By way of example, etch stop layer 28 has a thickness of 500 Å. Suitable materials for etch stop layer 28 include dielectric materials such as, for example, silicon oxynitride (SiON), silicon nitride (SiN), silicon rich nitride (SiRN), silicon carbide (SiC), hydrogenated oxidized silicon carbon material (SiCOH), or the like.

A layer of dielectric or insulating material 30 having a thickness ranging between approximately 1,000 Å and approximately 20,000 Å is formed on etch stop layer 28. Preferably, insulating layer 30 has a thickness ranging between 4,000 Å and 12,000 Å. By way of example, insulating layer 30 has a thickness of about 10,000 Å and comprises a material having a dielectric constant (K) lower than that of silicon dioxide, silicon nitride, or hydrogenated oxidized silicon carbon material (SiCOH). Although insulating layer 30 can be silicon dioxide, silicon nitride or SiCOH, using materials for insulating layer 30 having a lower dielectric constant than these materials lowers the capacitance of the metallization system and improves the performance of semiconductor component 10. Suitable organic low K dielectric materials include, but are not limited to, polyimide, spin-on polymers, poly(arylene ether) (PAE), parylene, xerogel, fluorinated aromatic ether (FLARE), fluorinated polyimide (FPI), dense SiLK, porous SiLK (p-SiLK), polytetrafluoroethylene, and benzocyclobutene (BCB). Suitable inorganic low κ dielectric materials include, but are not limited to, hydrogen silsesquioxane (HSQ), methyl silsesquioxane (MSQ), fluorinated glass, or NANOGLASS. It should be understood that the type of dielectric material for insulating layer 30 is not a limitation of the present invention and that other organic and inorganic dielectric materials may be used, especially dielectric materials having a dielectric constant less than that of silicon dioxide. Similarly, the method for forming insulating layer 30 is not a limitation of the present invention. For example, insulating layer 30 may be formed using, among other techniques, spin-on coating, spray-on coating, Chemical Vapor Deposition (CVD), Plasma Enhanced Chemical Vapor Deposition (PECVD), or Physical Vapor Deposition (PVD).

An etch stop layer 32 having a thickness ranging between approximately 5 Å and approximately 1,000 Å is formed on insulating layer 30. By way of example, etch stop layer 32 has a thickness of 500 Å. Suitable materials for etch stop layer 32 include dielectric materials such as, for example, silicon oxynitride (SiON), silicon nitride (SiN), silicon rich nitride (SiRN), silicon carbide (SiC), hydrogenated oxidized silicon carbon material (SiCOH), or the like. It should be noted that etch stop layer 32 is an optional layer. In other words, etch stop layer 32 may be absent from semiconductor component 10.

A layer of dielectric material 34 having a thickness ranging from approximately 2,000 Å to approximately 20,000 Å is formed on etch stop layer 32. Suitable materials and deposition techniques for dielectric layer 34 are the same as those listed for insulating layer 30. Although the material of dielectric layer 34 may be the same as that of insulating layer 30, preferably the dielectric material is different. In addition, it is preferable that the materials of dielectric layer 34 and insulating layer 30 have different etch rates, yet have similar coefficients of thermal expansion and be capable of withstanding the stress levels brought about by processing and use as a final product.

In accordance with one embodiment, the dielectric material of insulating layer 30 is p-SILK and the material of dielectric layer 34 is silicon oxynitride (SiON). Other suitable materials for dielectric layer 34 include silicon carbide and Ensemble (Ensemble is an interlayer dielectric coating sold by The Dow Chemical Co.). These materials can be applied using a spin-on coating technique and they have similar stress level tolerances and processing temperature tolerances. Moreover, these materials can be selectively or differentially etched with respect to each other. In other words, etchants are available that selectively etch the p-SILK and silicon oxynitride, i.e., an etchant can be used to etch the p-SILK but not significantly etch the silicon oxynitride and another etchant can be used to etch the silicon oxynitride but not significantly etch the p-SILK.

In accordance with another embodiment, the dielectric material of insulating layer 30 is foamed polyimide and the dielectric material of dielectric layer 34 is HSQ. Layers 30, 32, and 34 cooperate to form an insulating structure. Although these embodiments illustrate the use of an organic and an inorganic dielectric material in combination, this is not a limitation of the present invention. The dielectric materials of insulating layer 30 and dielectric layer 34 can both be either organic materials or inorganic materials, or a combination thereof.

Still referring to FIG. 1, a hardmask 36 having a thickness ranging between approximately approximately 100 Å and approximately 5,000 Å is formed on dielectric layer 34.6 Preferably, hardmask 36 has a thickness ranging between approximately 500 Å and approximately 1,000 Å and comprises a single layer of a dielectric material such as, for example, silicon oxynitride (SiON), silicon nitride (SiN), silicon rich nitride (SiRN), silicon carbide (SiC), or hydrogenated oxidized silicon carbon material (SiCOH). It should be noted that hardmask 36 is not limited to being a single layer system, but can also be a multi-layer system. Hardmask 36 should comprise a material having a different etch rate or selectivity and a different thickness than etch stop layers 28 and 32. Because hardmask 36 lowers the reflection of light during the photolithographic steps used in patterning a photoresist layer 42, it is also referred to as an Anti-Reflective Coating (ARC) layer.

Layer of photoresist 42 is formed on hardmask 36 and patterned to form openings 44 and 46 using techniques known to those skilled in the art.

Referring now to FIG. 2, the portions of hardmask 36 and dielectric layer 34 that are not protected by patterned photoresist layer 42, i.e., the portions exposed by openings 44 and 46, are etched using an anisotropic reactive ion etch to form openings 50 and 52 having sidewalls 55 and 56, respectively. The anisotropic etch stops or terminates in or on etch stop layer 32. In other words, the portions of hardmask 36 and dielectric layer 34 underlying or exposed by openings 44 and 46 are removed using the anisotropic reactive ion etch, thereby exposing portions of etch stop layer 32. Photoresist layer 42 is removed using techniques known to those skilled in the art.

Another layer of photoresist (not shown) is formed on the remaining portions of hardmask 36 and fills openings 50 and 52. The photoresist layer is patterned to form an opening (not shown) that exposes a portion of etch stop layer 32 underlying photoresist-filled opening 52. The exposed portion of etch stop layer 32 and the portion of insulating layer 30 underlying the exposed portion of etch stop layer 32 are etched using a reactive ion etch to form an inner opening 54 having sidewalls 57 that exposes a portion of etch stop layer 28. Thus, the reactive ion etch stops on etch stop layer 28, thereby exposing portions of etch stop layer 28. The photoresist layer is removed.

The exposed portions of etch stop layers 28 and 32 are etched using a reactive ion etch to expose portions of insulating layer 30 and metal layer 22. Preferably, the photoresist layer is removed prior to exposing insulating layer 30 because low κ dielectric materials that may comprise insulating layer 30 are sensitive to photoresist removal processes and may be damaged by them.

Opening 50 in combination with layers 30, 32, 34, and 36 form a single damascence structure, whereas openings 52 and 54 in combination with layers 28, 30, 32, 34, and 36 form a dual damascene structure. When an opening such as opening 50 will be used to electrically couple vertically spaced apart interconnect layers it is typically referred to as a via or an interconnect via, whereas when an opening such as opening 52 will be used to horizontally route electrically conductive lines or interconnects it is typically referred to as a trench or an interconnect trench.

Referring now to FIG. 3, a barrier 60 having a thickness ranging between approximately 5 Å and approximately 65 Å is formed on hardmask 36 and in openings 50, 52, and 54 (shown in FIG. 2). Barrier 60 is a multilayer structure comprising a conformal protective layer 62 and a conformal capping layer 64. In other words, protective layer 62 cooperates with capping layer 64 to form barrier 60. Protective layer 62 serves to prevent corrosion of conductive layers such as, for example, layer 22, whereas capping layer 64 serves to retard electromigration. Thus, protective layer 62 is also referred to as a corrosion inhibition or retardation layer and capping layer 64 is also referred to as an electromigration resistant or retardation layer.

Protective layer 62 is formed by conformally depositing an electrically conductive material using a non-halide based precursor in an Atomic Layer Deposition (ALD) process. By way of example, the material of protective layer 62 is metal nitride. Suitable metal nitride materials for protective layer 62 include tantalum nitride, tungsten nitride, and titanium nitride. Alternatively, protective layer 62 may be formed using a metal nitride that is doped with carbon or silicon. For example, protective layer 62 can be silicon doped tantalum nitride (TaSiN), carbon doped tantalum nitride (TaCN), silicon doped tungsten nitride (WSiN), carbon doped tungsten nitride (WCN), silicon doped titanium nitride (TiSiN), carbon doped titanium nitride (TiCN), or the like. An advantage of using atomic layer deposition is that it is capable of producing a highly densified thin, conformal layer or film using a non-halide based precursor such as, for example, an organometallic precursor. Examples of suitable organometallic precursors include, among others, pentakis(diethylamido)tantalum (PDEAT), t-butylimino tris(diethylamino)tantalum (TBTDET), ethylimino tris(diethylamino)tantalum (EITDET-c), pentakis(ethylmethylamido)tantalum (PEMAT), tridimethylamine titanate (TDMAT), tetrakis(diethlyamino)titanium (TDEAT), (trimethylvinylsilyl)hexafluoroacetylacetonato copper I, or tungsten hexacarbon-monoxide (W(CO)₆). The non-halide based precursors do not form by-products such as tantalum pentachloride or tantalum pentafluoride that corrode metals such as copper. Moreover, the conformal layers formed using these precursors are sufficiently dense that they need only be a few angstroms thick, e.g., 3 Å to 10 Å, to cover or protect any underlying metal layers. Because the protective layer can be so thin, interconnect layers comprising a barrier layer and a bulk electrically conductive material, e.g., copper, that are made in accordance with the present invention have a very low resistance. Preferably, protective layer 62 has a thickness ranging between approximately 5 Å and approximately 60 Å.

Capping layer 64 is formed by conformally depositing an electrically conductive material using an ALD process. Suitable materials for capping layer 64 include tantalum, tungsten, titanium, refractory metals, or the like. By way of example, capping layer 64 is a tantalum film formed using the ALD process with a reducing agent, where the tantalum is derived from either tantalum pentachloride (TaCl₅) or tantalum pentafluoride (TaF₅) and the reducing agent is either a hydrogen (H₂) plasma or an ammonia (NH₃) plasma. Capping layer 64 has a thickness ranging between approximately 1 Å and approximately 10 Å. Capping layer 64 provides a highly reliable interface with a subsequently deposited metal film such as, for example, copper, and improves electromigration resistance.

A film or layer 66 of an electrically conductive material is formed on capping layer 64 and fills openings 50, 52, and 54, thereby forming a metal-filled barrier-lined opening. By way of example layer 66 is copper which is plated on capping layer 64. Techniques for plating copper on a capping layer are known to those skilled in the art. Alternatively, layer 66 may be aluminum or silver.

Referring now to FIG. 4, copper film 66 is planarized using, for example, a Chemical Mechanical Polishing (CMP) technique having a high selectivity to hardmask 36. Thus, the planarization stops on hardmask 36. After planarization, portion 68 of copper film 66 remains in opening 50 and portion 70 of copper film 66 remains in openings 52 and 54, which openings are shown in FIG. 2. As those skilled in the art are aware, Chemical Mechanical Polishing is also referred to as Chemical Mechanical Planarization. The method for planarizing copper film 66 is not a limitation of the present invention. Other suitable planarization techniques include electropolishing, electrochemical polishing, chemical polishing, and chemical enhanced planarization.

Optionally, a passivation or protective layer (not shown) may be formed over portions 68 and 70 and over hardmask 36.

By now it should be appreciated that a semiconductor component having a metallization system comprising a conformal multi-layer barrier structure between an underlying structure and an electrically conductive material has been provided. The conformal multi-layer barrier structure is comprised of a capping layer disposed on a protective layer. The protective and capping layers of the multi-layer barrier structure are formed using atomic layer deposition, which allows formation of thin conformal layers. Further, the protective layer is formed using a precursor that does not produce by-products that may corrode metals such as copper. The atomic layer deposition process forms thin conformal layers that do not leave gaps or underlying material unprotected. Thus, the protective layer prevents metal contamination of any underlying layers. This is particularly important in the formation of copper interconnects. In addition, the formation of a continuous protective layer ensures strong bonding or adhesion of, for example, copper to the semiconductor component. The capping layer retards or reduces electromigration in the semiconductor component. The capping layer can be formed using halide based precursors because the protective layer prevents the by-products from corroding or pitting any material underlying the protective layer. Because the multi-layer barrier structure is thin, i.e., less than about 65 Å , most of the interconnect is comprised of an electrically conductive material such as copper, which has a low resistivity and is a very good thermal conductor. The method is suitable for integration with semiconductor processing techniques such as single and dual damascene processes. Another advantage of a metallization system manufactured in accordance with the present invention is that it is cost effective to implement in semiconductor component manufacturing processes.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

1. A method for manufacturing a semiconductor component, comprising:
providing a semiconductor substrate having a major surface and further providing an interconnect layer over the major surface;
forming a dielectric material over the interconnect layer;
forming an opening in the dielectric material, the opening having sidewalls;
forming a multi-layer barrier in the opening to form a barrier-lined opening; and
filling the barrier-lined opening with an electrically conductive material.

2. The method of claim 1, wherein forming the multi-layer barrier comprises forming a first layer of electrically conductive material in the opening using atomic layer deposition.

3. The method of claim 2, further including forming the first layer to have a thickness ranging between approximately 5 Å and approximately 60 Å.

4. The method of claim 3, further including forming the second layer to have a thickness ranging between approximately a monolayer and approximately 10 Å.

5. The method of claim 2, wherein forming the multi-layer barrier further comprises using a metal nitride as the electrically conductive material.

6. The method of claim 5, wherein the electrically conductive material is a metal nitride selected from the group of metal nitrides consisting of tantalum nitride, tungsten nitride, and titanium nitride.

7. The method of claim 6, wherein the electrically conductive material is doped with one of carbon or silicon.

8. The method of claim 6, wherein forming the first layer of electrically conductive material includes using a non-halide based precursor.

9. The method of claim 6, wherein forming the first layer of electrically conductive material includes using an organometallic precursor.

10. The method of claim 9, wherein the organometallic precursor is selected from the group of precursors consisting of pentakis(diethylamido)tantalum (PDEAT), t-butylimino tris(diethylamino)tantalum (TBTDET), ethylimino tris(diethylamino) tantalum (EITDETc), pentakis(ethylmethylamido)tantalum (PEMAT), tridimethylamine titanate (TDMAT), tetrakis(diethlyamino)titanium (TDEAT), (trimethylvinylsilyl)hexafluoroacetylacetonato copper l, and tungsten hexacarbon monoxide (W(CO)₆ ).

11. The method of claim 6, wherein forming the multi-layer barrier further comprises forming a second layer of electrically conductive material over the first layer of electrically conductive material using atomic layer deposition.

12. The method of claim 11, wherein forming the second layer of electrically conductive material includes using a metal selected from the group of metals consisting of tantalum, tungsten, and titanium.

13. The method of claim 11, wherein forming the second layer of electrically conductive material includes deriving the tantalum from one of tantalum pentachloride (TaCl₅) or tantalum pentafluoride (TaF₅ ).

14. The method of claim 13, wherein forming the second layer of electrically conductive material further includes using a reducing agent selected from the group of reducing agents consisting of hydrogen plasma and ammonia plasma.

15. A method for manufacturing a semiconductor component, comprising:
forming a damascene structure over a lower metal level, the damascene structure comprising an insulating material having a major surface and an opening extending into the insulating material;
forming a multi-layer barrier in the opening; and
forming an electrically conductive material over the multi-layer barrier.

16. The method of claim 15, wherein forming the electrically conductive multi-layer barrier comprises:
forming a first layer of electrically conductive material in the opening using atomic layer deposition; and
forming a second layer of electrically conductive material over the first layer of electrically conductive material using atomic layer deposition.

17. The method of claim 16, wherein forming the first layer of electrically conductive material comprises using a metal nitride as the electrically conductive material, the metal nitride selected from the group of metal nitrides consisting of tantalum nitride, tungsten nitride, and titanium nitride.

18. The method of claim 16, wherein forming the first layer of electrically conductive material includes using an organometallic precursor selected from the group of precursors consisting of pentakis(diethylamido)tantalum (PDEAT), t-butylimino tris(diethylamino)tantalum (TBTDET), ethylimino tris(diethylamino) tantalum (EITDETc) pentakis(ethylmethylamido)tantalum (PEMAT), tridimethylamine titanate (TDMAT), tetrakis(diethlyamino)titanium (TDEAT), (trimethylvinylsilyl)hexafluoroacetylacetonato copper I, and tungsten hexacarbon monoxide (W(CO)₆).

19. The method of claim 16, further including forming the first layer of electrically conductive material to have a thickness ranging between approximately 5 Å and approximately 60 Å and the second layer of electrically conductive material to have a thickness ranging between approximately 1 Å and approximately 10 Å.

20. The method of claim 16, further including using tantalum pentachloride (TaCl₅) to form the second layer of electrically conductive material.

21. The method of claim 20, further including using a reducing agent selected from the group of reducing agents consisting of hydrogen plasma and ammonia plasma.

22. The method of claim 16, further including using tantalum pentafluoride (TaF₅) to form the second layer of electrically conductive material.

23. The method of claim 22, further including using a reducing agent selected from the group of reducing agents consisting of hydrogen plasma and ammonia plasma.

24. The method of claim 16, wherein forming the second layer includes using a metal selected from the group of metals consisting of tantalum, tungsten, and titanium.

25. The method of claim 16, wherein forming the first layer of electrically conductive material includes using a non-halide based precursor.

26. The method of claim 15, wherein forming the electrically conductive material over the multi-layer barrier includes using a metal selected from the group of metals consisting of copper, aluminum, and silver.

27. A method for reducing electromigration in a semiconductor component, comprising:
providing a damascene structure over a lower electrically conductive level, the damascene structure comprising a dielectric material having a major surface and an opening extending into the dielectric material;
lining the opening and a portion of the major surface with a first layer of electrically conductive material to form a barrier-lined opening;
lining the first layer of electrically conductive material with a second layer of electrically conductive material, the first and second layers of electrically conductive material cooperating to form a multi-layer barrier film; and
disposing a metal over the multi-layer barrier film.

28. The method of claim 27, wherein lining the opening and the portion of the major surface includes forming the first layer of electrically conductive material using atomic layer deposition.

29. The method of claim 28, wherein forming the first layer of electrically conductive material includes using a metal nitride selected from the group of metal nitrides consisting of tantalum nitride, tungsten nitride, and titanium nitride.

30. The method of claim 28, wherein forming the first layer of electrically conductive material includes using an organometallic precursor selected from the group of precursors consisting of pentakis(diethylamido)tantalum (PDEAT), t-butylimino tris(diethylamino)tantalum (TBTDET), ethylimino tris(diethylamino) tantalum (EITDET-c) pentakis(ethylmethylamido)tantalum (PEMAT), tridimethylamine titanate (TDMAT), tetrakis(diethlyamino)titanium (TDEAT), (trimethylvinylsilyl)hexafluoroacetylacetonato copper I, and tungsten hexacarbon monoxide (W(CO)₆).

31. The method of claim 28, wherein forming the second layer of electrically conductive material includes using a halide based precursor.

32. The method of claim 31, wherein the halide containing precursor is one of tantalum pentachloride (TaCl₅) or tantalum pentafluoride (TaF₅).

33. A semiconductor component, comprising:
a damascene structure over a lower electrically conductive level, the damascene structure comprising a dielectric material having a major surface and an opening extending into the dielectric material;
a multi-layer barrier lining the opening and a portion of the major surface; and
an electrically conductive material disposed on the multi-layer barrier in the opening.

34. The semiconductor component of claim 33, wherein the multi-layer barrier comprises:
a first layer of electrically conductive material lining the opening and the portion of the major surface; and
a second layer of electrically conductive material disposed on the first layer of electrically conductive material.

35. The semiconductor component of claim 34, wherein the first layer of electrically conductive material comprises a metal nitride and the second layer of electrically conductive material comprises a refractory metal.

36. The semiconductor component of claim 33, wherein the multi-layer barrier has a thickness ranging between approximately 5 Å and approximately 65 Å.

37. The semiconductor component of claim 33, wherein the electrically conductive material disposed on the multi-layer barrier is one of copper, aluminum, or silver.
